(19) United States
(12) Patent Application Publication
(10) Pub. No.: US 2010/0237064 A1
(43) Pub. Date: Sep. 23, 2010

(54) ELECTROMAGNETIC MODULE OF ELECTRONIC APPARATUS AND MANUFACTURING PROCESS THEREOF

(75) Inventors: Hsi-An Liu, Taoyuan Hsien (TW); I-Shen Lin, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/723,432

(22) Filed: Mar. 12, 2010

(30) Foreign Application Priority Data
Mar. 20, 2009 (TW) 098109243

(51) Int. Cl. H05B 6/12; H05K 13/00

(52) U.S. Cl. 219/622; 29/602.1

(57) ABSTRACT

An electromagnetic module applied in an electronic apparatus having a circuit board is disclosed. The electromagnetic module includes a plate disposed on the circuit board, and an inductor coil assembly. The inductor coil assembly includes a magnetic core assembly, a first insulation layer and a coil, which are stacked on the plate in order. The inductor coil assembly is electrically connected to the circuit board for generating the electromagnetic induction, thereby the eddy current is generated to produce heat when a pot disposed on the electronic apparatus. In addition, a process for manufacturing an electromagnetic module, applied in an electronic apparatus is disclosed. The process includes the following steps: (a) providing a plate, (b) attaching a magnetic core assembly to the plate, (c) correspondingly disposing a first insulation layer on the magnetic core assembly, and (d) correspondingly disposing a coil on the first insulation layer.

### FIELD OF THE INVENTION

The present invention relates to an electromagnetic module, and more particularly to an electromagnetic module applied in an electronic apparatus and a process for manufacturing the electromagnetic module.

### BACKGROUND OF THE INVENTION

Accompanying the development and advancement of electronic industry, cooking is not limited to use traditional stove. The household appliances such as electric pot, induction cooktop, microwave oven are developed and advanced at every moment, and become the indispensable electronic product for human's daily life in the past few years.

The induction cooktop is invented by using the principle of electromagnetic induction. When the induction cooktop is supplied power from a power source, the magnetic field is generated at the coils of induction cooktop, which is passed by the electric current. In the meantime, while a conducting device, for example iron pot, steel pot, metal pot . . . , is disposed in the magnetic field which changes alone with time, the magnetic flux passing the conducting device will change and the eddy current is generated to resist the change of magnetic flux. When the eddy current passing through the resistant of the conducting device, heat is generated. Accordingly, the pot as a conducting device can generate heat speedily for heating or cooking food in the pot to achieve the cooking function.

Comparatively speaking, the heating principle of a traditional stove, such as electric fire, petroleum stove, gas stove, and automatic rice cooker, is to heat the food inside the pot directly by burning the bottom of the pot. A part of heat energy will be consumed on heating air, so the thermal efficiency is around 40-65%. Hence, the traditional stove has the disadvantages of high energy consumption and slow cooking. However, the heating resource of the induction cooktop comes from the eddy current of the bottom of the pot, but not the heat conduction of the induction cooktop, so the thermal efficiency is generally higher than 80%. The heating efficiency of the induction cooktop is more than one time in comparison with that of others. For example, the time for boiling a pot of water by using the traditional stove requires 9 minutes, but only requires 2-3 minutes by using the induction cooktop. Thus, not only the consumption time is reduced, but also the energy is substantially saved.

For the using safety, the effect of the induction cooktop is totally different from that of the gas stove. During using, the induction cooktop not only does not produce fire, but also does not generate heat on the cover thereof. Furthermore, none of components inside the induction cooktop has temperature higher than 250 C. Thus, there is no burn accident happens. In addition, once the pot is removed from the cover of the induction cooktop, it will automatically cut off the power supply. Therefore, it is very safe stove.

Since the induction cooktop has higher energy efficiency than the traditional stoves, and has the advantages of heating fast, no fire, no smoke, no hazard gas, no heat radiation, small size, safety, nice-looking, it can easily achieve most cooking tasks, the effects of environment protection, energy saving, and power saving. Thus, the traditional stove is gradually replaced by the induction cooktop in current daily life.

For popularizing the induction cooktop, it is necessary to lower manufacture cost. However, it is necessary to assemble and position the components such as inductor coils, insulation board, magnetic core assembly to a positioning plate one by one to form an electromagnetic assembly during the manufacture process of the induction cooktop. Subsequently, the electromagnetic assembly is positioned on a metal plate inside the induction cooktop. It is not only time and labor consumptions for components assembling and twice positioning procedures, but also cost increase according to the traditional process. For example, in prior art, a set of inductor coils and a magnetic core assembly need to be disposed on one positioning plate. Hence, more coil ranges the induction cooktop includes, more positioning plates are required. It especially causes higher cost and more complicated process.

Therefore, the purpose of the present invention is to develop an electronic apparatus having an electromagnetic module to deal with the above situations encountered in the prior art.

### SUMMARY OF THE INVENTION

An object of the present invention is to provide an electromagnetic module of an electronic apparatus for decreasing the cost, simplifying the procedure and increasing efficiency in the manufacturing process.

Another object of the present invention is to provide a manufacture process of an electromagnetic module of an electronic apparatus for decreasing the cost, simplifying the procedure and increasing efficiency in the manufacturing process.

According to an aspect of the present invention, there is provided an electronic apparatus. The electronic apparatus includes a housing including an accommodating space and an opening, a circuit board disposed in the accommodating space, a cover covering on the opening, and an electromagnetic module. The electromagnetic module includes a plate disposed on the circuit board, and an inductor coil assembly including a magnetic core assembly, a first insulation layer and a coil, which are stacked on the plate in order. The inductor coil assembly is electrically connected to the circuit board for generating the electromagnetic induction, thereby the eddy current is generated to produce heat when a pot disposed on the electronic apparatus.

According to another aspect of the present invention, there is provided an electromagnetic module, applied in an electronic apparatus having a circuit board. The electromagnetic module includes a plate disposed on the circuit board, and an inductor coil assembly. The inductor coil assembly includes a magnetic core assembly, a first insulation layer and a coil, which are stacked on the plate in order. The inductor coil assembly is electrically connected to the circuit board for generating the electromagnetic induction, thereby the eddy current is generated to produce heat when a pot disposed on the electronic apparatus.

According to an additional aspect of the present invention, there is provided a process for manufacturing an electromagnetic module, applied in an electronic apparatus. The process includes the following steps: (a) providing a plate, (b) attaching a magnetic core assembly to the plate, (c) correspondingly disposing a first insulation layer on the magnetic core assembly, and (d) correspondingly disposing a coil on the first insulation layer.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is an exploded structure diagram illustrating a preferred embodiment of an electronic apparatus according to the present invention;

FIG. 2 is an exploded structure diagram illustrating an electromagnetic module of FIG. 1; and

FIG. 3 is a structure diagram illustrating the assembled electromagnetic module of FIG. 2.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

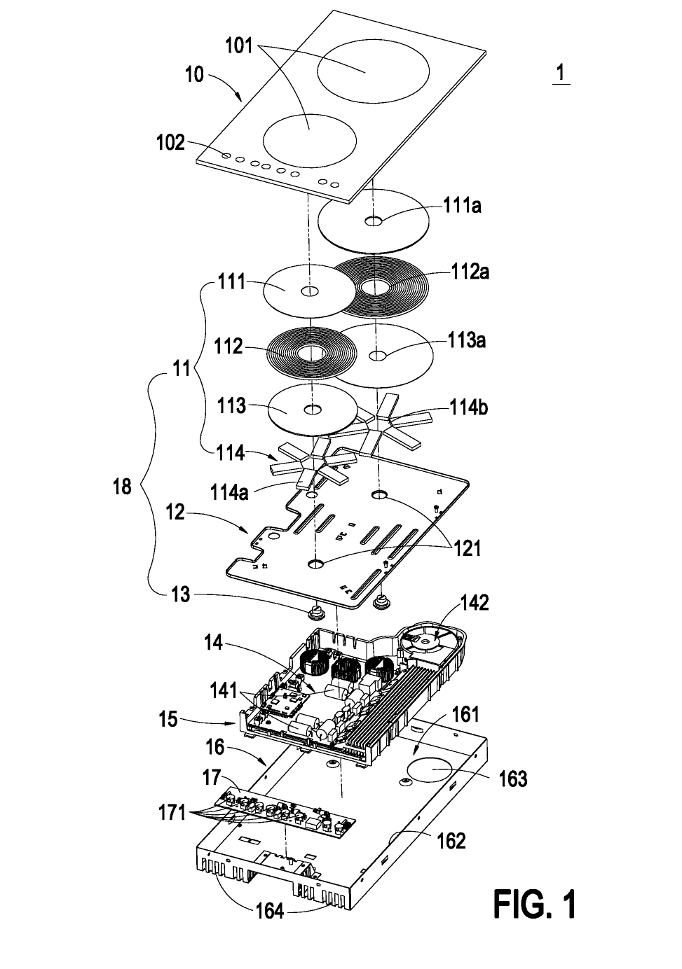

FIG. 1 is an exploded structure diagram illustrating a preferred embodiment of an electronic apparatus according to the present invention. In this preferred embodiment, the electronic apparatus can be an induction cooktop 1, but it is not limited to. As shown in FIG. 1, the induction cooktop 1 includes a cover 10, an electromagnetic module 18, a circuit board 14 and a housing 16. The housing 16 is square-shaped and has a hollow structure. The housing 16 can be integrally formed and made of iron material, but it is not limited to. In addition, the housing 16 includes an accommodating space 161 and an one-side opening 162, which are joined for accommodating the devices such as the circuit board 14, the electromagnetic module 18 . . . etc. Moreover, the housing 16 has an opening 163 disposed on the bottom thereof for air-entering, and a plural of air-out openings 164 disposed on one lateral-side thereof.

In some preferred embodiment, the induction cooktop 1 further includes an accommodating frame 15 for accommodating the circuit board 14 and an active heat-dissipating device. The circuit board 14 has a plural of electric elements 141. In this embodiment, the active heat-dissipating device is a fan 142. The fan 142 is correspondingly disposed on the opening 163 of the bottom of the housing 16, for drawing in the air from outside to blow the heat-generated electric elements 141 of the circuit board 14. Hence, it will force an airflow formed to dissipate the heat from the circuit board 14. Therefore, the hot air will dissipate from the air-out openings 164 of the housing 16 for achieving the heat-dissipating cycle of the induction cooktop 1.

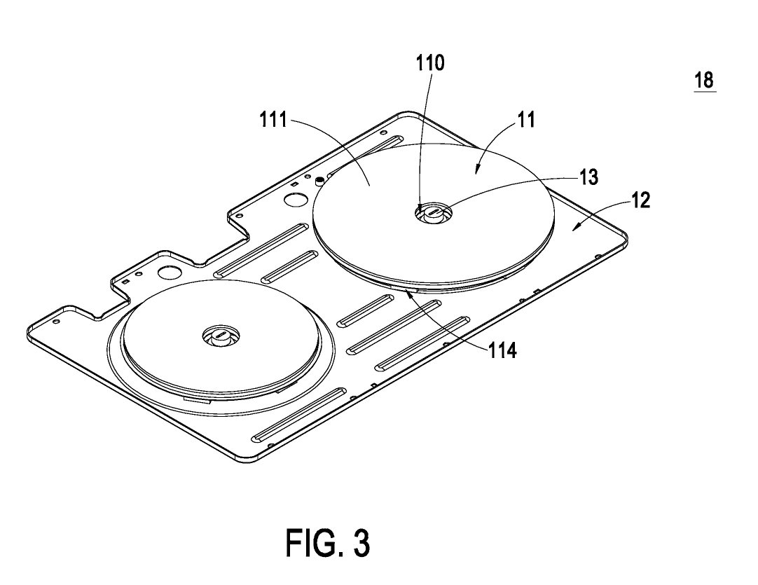

As shown in FIG. 1, the electromagnetic module 18, disposed on the circuit board 14 and the accommodating frame 15, includes an inductor coil assembly 11 and a plate 12. The inductor coil assembly 11 includes a coil 112, a first insulation layer 113 and a magnetic core assembly 114, which are stacked on the plate 12 in order. The inductor coil assembly 11 is electrically connected to the circuit board 14 for generating the electromagnetic induction in the electromagnetic module 18, thereby the eddy current is generated to produce heat when a pot disposed on the induction cooktop 1 (not shown in FIG. 1). Certainly, the number of the inductor coil assembly 11 can optionally be changed, such as one, two or four. In addition, the induction cooktop 1 further includes a temperature sensor 13 correspondingly passed through a channel 110 (as shown in FIG. 3) formed by the coil 112, a first insulation layer 113, the magnetic core assembly 114 and the plate 12, for detecting the temperature of the electromagnetic module 18 and starting safety system once the temperature is too high.

Please refer to FIG. 1. The cover 10 is made of insulation or heat-resistant hard materials, such as glass and ceramics, but it is not limited to. The cover 10 is disposed on the inductor coil assembly 11 and the position of the cover 10 corresponded to the inductor coil assembly 11 is a coil range 101. The coil range 101 can be made by different material or different color plate for labeling the position to put the pot. Preferably, the pot is made of metal, but it is not limited to. In addition, as shown in FIG. 1, the induction cooktop 1 further includes a control device 17 disposed in the housing 16. Furthermore, the control device 17 includes at least one operation element 171 corresponded to an operation button 102 for providing the user to operate the induction cooktop 1 via touching or pressing the operation button 102.

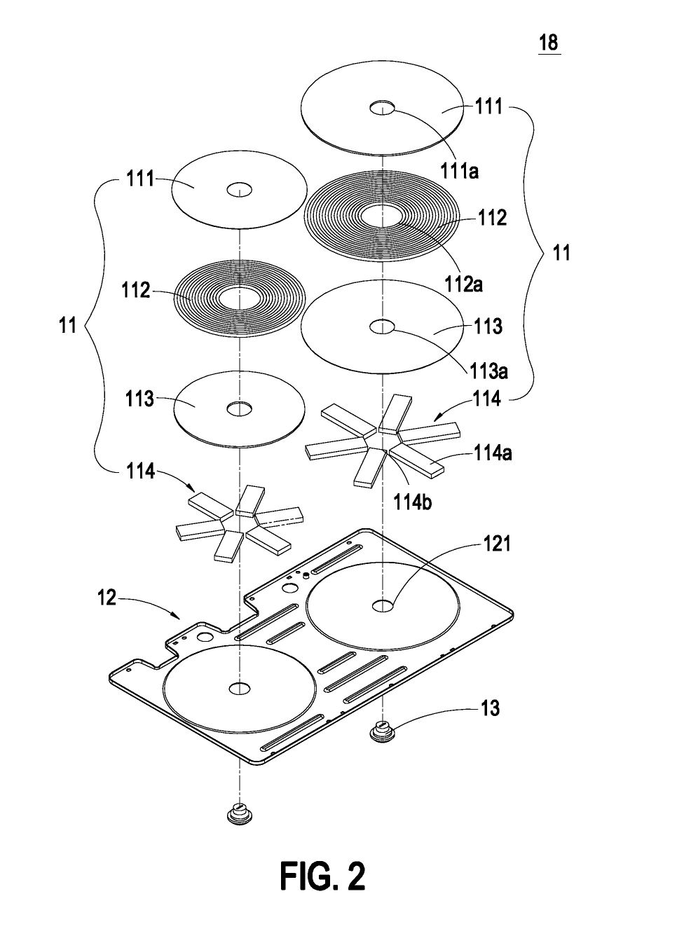

Please refer to FIG. 2 which is an exploded structure diagram illustrating an electromagnetic module of FIG. 1. As shown in FIG. 2, the electromagnetic module 18 includes the inductor coil assembly 11 and the plate 12. The plate 12 is a flat board, which can preferably be made by heat-conductible but not magnetic-conductible material. In this embodiment, the plate 12 is made of aluminum, but it is not limited to. The plate 12 includes a first opening 121. Since there are two sets of the inductor coil assembly 11 of the electromagnetic module 18 in this preferred embodiment, the plate 12 has two first openings 121 for corresponding to the two sets of the inductor coil assembly 11, respectively. As shown in FIG. 2, besides the coil 112, the first insulation layer 113 and the magnetic core assembly 114, the inductor coil assembly 11 further includes a second insulation layer 111. That is, the inductor coil assembly 11 is assembled by stacking the second insulation layer 111, the coil 112, the first insulation layer 113 and the magnetic core assembly 114 in order. The magnetic core assembly 114 includes a plural of magnetic cores 114a. The plural magnetic cores 114a are radially arranged around the first opening 121 as the center of circle to form a second opening 114a. The magnetic core assembly 114 is stuck to the plate 12 by a heat-resistant adhesion agent (not shown in FIG. 2). Preferably, the heat-resistant adhesion agent is a heat-resistant glue, but it is not limited to.

Please refer to FIG. 2. The first insulation layer 113 is disposed between the coil 112 and the magnetic core assembly 114 for insulating them and maintaining an electric safe distance. The first insulation layer 113 is made of heat-resistant insulation material such as mica sheet, but it is not limited to. Furthermore, the first insulation layer 113 includes a third opening 113a correspondingly disposed to the first and second openings 121 and 114b. Moreover, the inductor coil assembly 112 includes a fourth opening 112a correspondingly disposed to the third opening 113a. The second insulation layer 111 is disposed between the inductor coil assembly 112 and the cover 10 (as shown in FIG. 1) for insulating them. The second insulation layer 111 also includes a fifth opening 111a correspondingly disposed to the fourth opening 112a. Similarly, the second insulation layer 111 is made of heat-resistant insulation material such as mica sheet, but it is not limited to.

FIG. 3 is a structure diagram illustrating the assembled electromagnetic module of FIG. 2. Please refer to FIGS. 2 and 3. The electromagnetic module 18 is assembled by directly sticking the magnetic core assembly 114 on the plate 12 via the heat-resistant adhesion agent and by corresponding the second opening 114b of the magnetic core assembly 114 to the first opening 121 of the plate 12. Subsequently, the first insulation layer 113, the coil 112 and the second insulation layer 111 are correspondingly stuck on the magnetic core assembly 114 in order. Furthermore, the third opening 113a, the fourth opening 112a and the fifth opening 111a are corresponded to the first and second openings 121 and 114b to form the channel 110. Subsequently, the temperature sensor 13 is passed through and disposed in the channel 110 and the coil 112 is electrically connected to the circuit board 14. Hence, the coil 112 will generate the electromagnetic induction with the magnetic core assembly 114 when the current passes through it, thereby the eddy current is generated to produce heat when a pot disposed on the induction cooktop 1. Simultaneously, the temperature of the electromagnetic module 18 is monitored by the temperature sensor 13 passed through and disposed in the channel 110.

Since the magnetic core assembly 114 is directly attached to the plate 12 by the heat-resistant adhesion agent, it is unnecessary to employ the positioning plate and the steps of disposing all assemblies on the positioning plate item by item and re-disposing on the plate 12. Hence, the process is simpler because it is unnecessary to do twice positioning procedures. Moreover, the cost of the positioning plate can be saved; especially the induction cooktop 1 includes more than one inductor coil assembly 11.

To sum up, the electronic apparatus according to the present invention includes the housing, the circuit board, the cover and electromagnetic module. The electromagnetic module according to the present invention includes the inductor coil assembly and the plate. The inductor coil assembly includes the magnetic core assembly, the first insulation layer and the coil, which are directly stacked on the plate in order. The inductor coil assembly is electrically connected to the circuit board for generating the electromagnetic induction in the electromagnetic module, thereby the eddy current is generated to produce heat when a pot disposed on the electronic apparatus. Therefore, the electromagnetic module of the electronic apparatus according to the present invention can largely cost down and simplify the procedure in the manufacturing process to increase efficiency.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic apparatus comprising:
a housing including an accommodating space and an opening;
a circuit board disposed in said accommodating space;
a cover covering on said opening; and
an electromagnetic module comprising:
a plate disposed on said circuit board; and
an inductor coil assembly including a magnetic core assembly, a first insulation layer and a coil, which are stacked on said plate in order, and said inductor coil assembly being electrically connected to said circuit board for generating the electromagnetic induction, thereby the eddy current is generated to produce heat when a pot disposed on said electronic apparatus.

2. The electronic apparatus according to claim 1 wherein said electronic apparatus is an induction cooktop and said pot is a metal pot.

3. The electronic apparatus according to claim 1 wherein said magnetic core assembly comprises a plural of magnetic cores and is stuck on said plate by a heat-resistant adhesion agent.

4. The electronic apparatus according to claim 1 wherein said first insulation layer is made of heat-resistant insulation material.

5. The electronic apparatus according to claim 1, further comprising a second insulation layer disposed on said coil.

6. The electronic apparatus according to claim 5 wherein said second insulation layer is made of heat-resistant insulation material.

7. The electronic apparatus according to claim 1 wherein said electromagnetic module further comprises a temperature sensor correspondingly passed through a channel of said electromagnetic module.

8. The electronic apparatus according to claim 1 wherein said plate is made of aluminum.

9. The electronic apparatus according to claim 1, further comprising an accommodating frame disposed in said accommodating space for accommodating said circuit board.

10. The electronic apparatus according to claim 1, further comprising an active heat-dissipating device.

11. The electronic apparatus according to claim 1, further comprising a control device disposed in said housing.

12. An electromagnetic module, applied in an electronic apparatus having a circuit board, comprising:
a plate disposed on said circuit board; and
an inductor coil assembly including a magnetic core assembly, a first insulation layer and a coil, which are stacked on said plate in order, and said inductor coil assembly being electrically connected to said circuit board for generating the electromagnetic induction, thereby the eddy current is generated to produce heat when a pot disposed on said electronic apparatus.

13. The electromagnetic module according to claim 12 wherein said electronic apparatus is an induction cooktop and said pot is a metal pot.

14. The electromagnetic module according to claim 12 wherein said magnetic core assembly comprises a plural of magnetic cores and is stuck on said plate by a heat-resistant adhesion agent.

15. The electromagnetic module according to claim 12, further comprising a second insulation layer disposed on said coil.

16. The electromagnetic module according to claim 12, further comprising a temperature sensor correspondingly passed through a channel of said electromagnetic module.

17. A process for manufacturing an electromagnetic module, applied in an electronic apparatus, comprising the following steps:
(a) providing a plate;
(b) attaching a magnetic core assembly to said plate;
(c) correspondingly disposing a first insulation layer on said magnetic core assembly; and
(d) correspondingly disposing a coil on said first insulation layer.

18. The process according to claim 17 wherein said magnetic core assembly is stuck on said plate by a heat-resistant adhesion agent.

19. The process according to claim 17, further comprising the step (d1) correspondingly disposing a second insulation layer on said coil after the step (d).

20. The process according to claim 19, further comprising the step (d2) correspondingly passing through a temperature sensor into a channel jointly formed by said plate, said magnetic core assembly, said first insulation layer, said coil and said second insulation layer after the step (d1).
